(19) United States
(12) Patent Application Publication
(10) Pub. No.: US 2013/0081663 A1
(43) Pub. Date: Apr. 4, 2013

(54) THERMOELECTRIC MODULE

(71) Applicants: Ju Hwan YANG, Gyeonggi-do (KR); Kang Heon Hur, Gyeonggi-do (KR); Sung Ho Lee, Gyeonggi-do (KR); Dong Hyeok Choi, Gyeonggi-do (KR)

(72) Inventors: Ju Hwan YANG, Gyeonggi-do (KR); Kang Heon Hur, Gyeonggi-do (KR); Sung Ho Lee, Gyeonggi-do (KR); Dong Hyeok Choi, Gyeonggi-do (KR)

(73) Assignee: SAMSUNG ELECTRO-MECHANICS CO., LTD.

(21) Appl. No.: 13/620,925

(22) Filed: Sep. 15, 2012

(30) Foreign Application Priority Data
Sep. 29, 2011 (KR) 10-2011-0099222

(51) Int. Cl. H01L 35/32; F25B 21/02

(52) U.S. Cl. 136/203

(57) ABSTRACT

The present invention relates to a thermoelectric module, there is provided a thermoelectric module including a metal layer surface treated for securing roughness at one surface thereof and a top substrate and a bottom substrate made of an insulating film formed on the surface treated one surface.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2011-0099222, entitled filed Sep. 29, 2011, which is hereby incorporated by reference in its entirety into this application.

### BACKGROUND OF THE INVENTION

1. Field of the Invention

The present invention relates to a thermoelectric module, and more particularly, to a thermoelectric module having a structure capable of improving the efficiency of heat transfer.

2. Description of the Related Art

A thermoelectric module has generally two applications, i.e., electric generation using Seebeck effect or cooling using Peltier effect.

Examining the principle of cooling, if a direct current voltage is applied to the electrodes of both ends of a thermoelectric device, the temperature of a heat absorbing part is reduced by moving heat according to the flow of electrons in an N-type thermoelectric device and according to the flow of holes in a P-type thermoelectric device, whereas the temperature is increased in a heat discharging part.

FIG. 1 is a partially cut perspective view schematically showing a conventional thermoelectric module. Referring to FIG. 1, the conventional thermoelectric module 1 includes P-type thermoelectric materials 3 and N-type thermoelectric materials 5. The thermoelectric materials 3 and 5 are electrically connected to a plurality of electrodes 9 in series by attaching the metal electrodes 9 with a predetermined pattern to a pair of insulating substrates 6 and 7 made of ceramic or silicon nitride.

In the conventional thermoelectric module 1, if the direct current voltage is applied to the metal electrodes 9 through a lead line 4 connected to a terminal, due to Peltier effect, heat is generated at a side where the current flows from the P-type thermoelectric materials 3 to the N-type thermoelectric materials 5, vice versa, heat is absorbed at a side where the current flows from the N-type thermoelectric materials 5 to the P-type thermoelectric materials 3. Accordingly, the insulating substrate 6 joined to the heat generation side is heated and the insulating substrate 7 joined to the heat absorption side is cooled.

Accordingly, the insulating substrates 6 and 7 are made of material to secure insulation to the metal electrodes 9 and to have an excellent thermal conductivity for the higher heat transfer, simultaneously.

However, since the insulating substrates included in the conventional thermoelectric module are made of the ceramic material for the insulation with the metal electrodes, the ceramic material secure the insulation with the metal electrodes, but it causes to reduce the efficiency of heat transfer of thermoelectric module due to the low thermal conductivity.

### SUMMARY OF THE INVENTION

The present invention has been invented in order to overcome the above-described problems and it is, therefore, an object of the present invention to provide a thermoelectric module having a structure capable of improving the efficiency of heat transfer.

In accordance with one aspect of the present invention to achieve the object, there is provided a thermoelectric module provided with a top substrate, a bottom substrate, a metal electrode formed on one surfaces of the top substrate and the bottom substrate and a plurality of P-type thermoelectric semiconductor and a plurality of N-type thermoelectric semiconductor separated between the metal electrodes, the thermoelectric module: including a metal layer surface treated to allow the top substrate, the bottom substrate or the top and bottom substrate to secure roughness at one surface thereof; and an insulating film formed on the surface treated surfaced thermoelectric module.

Further, wherein the insulating film is composed of polymer resin.

Further, the polymer resin is made of a material including any one among epoxy, poly imide and poly amide.

Further, a ceramic filler is filled in the polymer resin.

Further, the ceramic filler is made of a material including any one among alumina, aluminum nitride, boron nitride and silica.

Further, the ceramic filler is contained more than 70 w % in comparison with the polymer resin.

Further, particles of the ceramic filler are different from each other in size.

Further, the ceramic filler includes granulation powder having particle sizes ranging between 2 μm and 3 μm and fine powder having particle sizes ranging between 0.3 μm and 0.5 μm.

Further, a metal filler is filled in the polymer resin.

Further, the metal filler is made of a material including more than one of Cu, Ag, Au, Al and W.

Further, the metal filler has content below 50 wt % in comparison with the polymer resin.

Further, each of the metal fillers has a different size.

Further, the metal filler includes granulation powder having particle sizes ranging between 2 μm and 3 μm and fine powder having particle sizes ranging between 0.3 μm and 0.5 μm.

Further, the ceramic filler and the metal filler is filled in the polymer resin.

Further, the ceramic filler is made of a material including more than any one of alumina, aluminum nitride, boron nitride and silica; and the metal filler is made of a material including more than any one of Cu, Ag, Au, Al and W.

Further, the ceramic fillers and the metal fillers are different in size.

Further, the ceramic filler and the metal filler includes granulation powder having particle sizes ranging between 2 μm and 3 μm and fine powder having particle sizes ranging between 0.3 μm and 0.5 μm.

Further, the insulating film has a thickness ranging from 10 μm to 30 μm.

Further, the metal layer has a thickness ranging from 100 μm to 200 μm.

Further, the metal layer has a thickness ranging from 100 μm to 200 μm.

Further, the metal layer is made of a material including more than any one of Cu, Au, Ag, AlN, SiC and Al.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a partially cut perspective view schematically showing a conventional thermoelectric module;

FIG. 2 is a front side view of a thermoelectric module in accordance with the present invention;

FIG. 3a is a front perspective view showing exploded a structure of a bottom substrate included in the thermoelectric module in accordance with the present invention;

FIG. 3b is a front side view showing a joined structure of the bottom substrate;

FIG. 4a is a view showing a surface of a metal layer before a blacken is performed;

FIG. 4b is a view showing a surface of a metal layer after a blacken is performed; and

FIG. 5 is a cross-section view of an insulating film included in the bottom substrate.

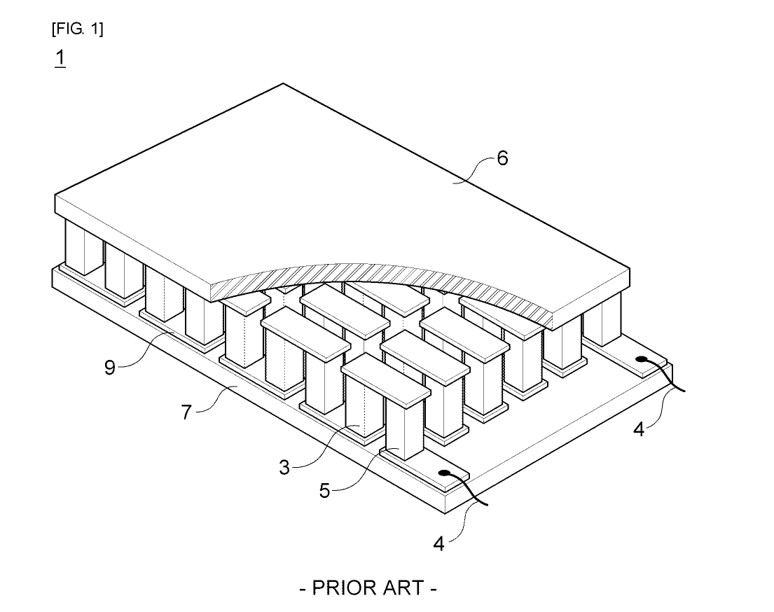

### DETAILED DESCRIPTION OF THE PREFERABLE EMBODIMENTS

Hereinafter, embodiments of the present invention will be described in detail with reference to the accompanying drawings. The following embodiments are provided as examples to fully convey the spirit of the invention to those skilled in the art.

Therefore, the present invention should not be construed as limited to the embodiments set forth herein and may be embodied in different forms. And, the size and the thickness of an apparatus may be overdrawn in the drawings for the convenience of explanation. The same components are represented by the same reference numerals hereinafter.

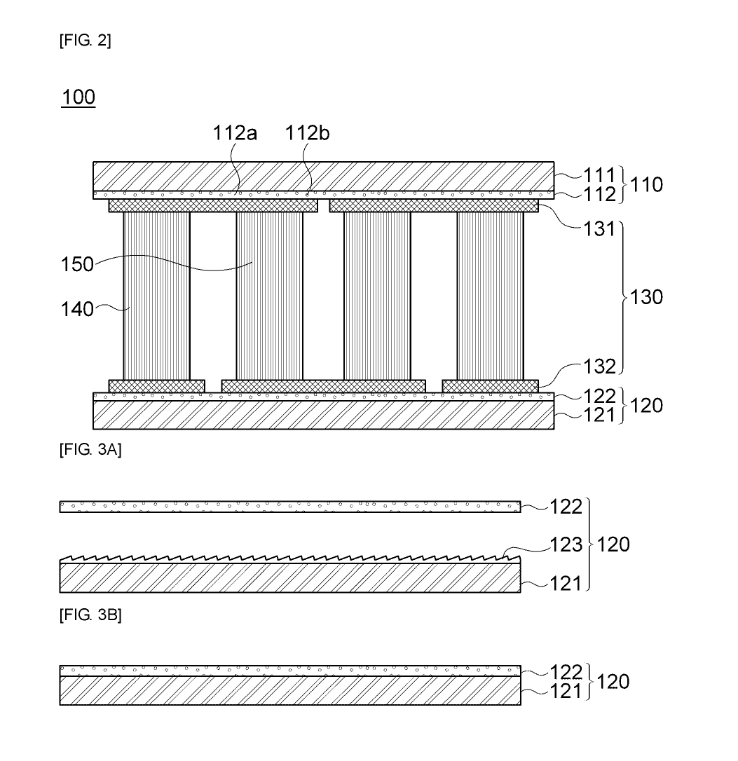

FIG. 2 is a front side view of a thermoelectric module in accordance with the present invention, FIG. 3a is a front perspective view showing exploded a structure of a bottom substrate included in the thermoelectric module in accordance with the present invention and FIG. 3b is a front side view showing a joined structure of the bottom substrate of FIG. 3a.

Referring to FIG. 2, FIG. 3a and FIG. 3b, the thermoelectric module 100 may include a top substrate 110 and a bottom substrate 120, metal electrodes 130 provided on one surfaces of the top substrate 110 and the bottom substrate 120 and a plurality of N-type thermoelectric semiconductor 140 and N-type thermoelectric semiconductor 150 separated between the metal electrodes 130.

If electric power is applied to the thermoelectric module, the metal electrodes 130 allows the current to flow into the P-type thermoelectric semiconductor 140 and the thermoelectric semiconductor 150, and; more particularly examining, they can be composed of top electrodes 131 formed on a bottom surface of the top substrate 110 and bottom electrodes 132 formed on a top surface of the bottom substrate 120.

The metal electrodes 130 can be formed of a material having high electric conductivity in order to minimize the loss of power supplied to the thermoelectric module; and, more particularly, it is preferable that they are formed of a material such as Ag or Cu and the like having an excellent conductivity.

The P-type thermoelectric semiconductor 140 and the N-type thermoelectric semiconductor 150 can be formed on one surface of the top electrode 131 and the bottom electrode 132, respectively by one. More particularly, the P-type thermoelectric semiconductor 140 can be formed on a left side of the bottom surface of the top electrode 131 and the N-type thermoelectric semiconductor 150 can be formed on a place where separated to a right side from the P-type thermoelectric semiconductor 140.

And, the N-type thermoelectric semiconductor 150 can be formed on the left side of the top surface of the bottom electrode 132 and the P-type thermoelectric semiconductor 140 can be formed on a place where separated to the right side from the N-type thermoelectric semiconductor 150.

Accordingly, if the electric power is applied to the thermoelectric module 100 in accordance with the present invention, the current becomes to flow by allowing the P-type thermoelectric semiconductor 140 to be electrically connected to the N-type thermoelectric semiconductor 150, the holes in the P-type thermoelectric semiconductor 140 are moved to the side of “−” with heat due to the Peltire effect, the top substrate 110 is heated by allowing the electrons in the N-type thermoelectric semiconductor 150 to be moved to the side of “+” with heat and the bottom substrate 120 is cooled.

In order to secure roughness, the top substrate 110 and the bottom substrate 120 can include a pair of surface treated metal layers 111 and 121 and a pair of insulating films 112 and 122 formed on the surface treated surface.

In order to improve the adhesion between the metal layers 111 and 121 and the insulating films 112 and 122, the surfaces of the metal layers 111 and 121 can be surface treated to secure the roughness thereof.

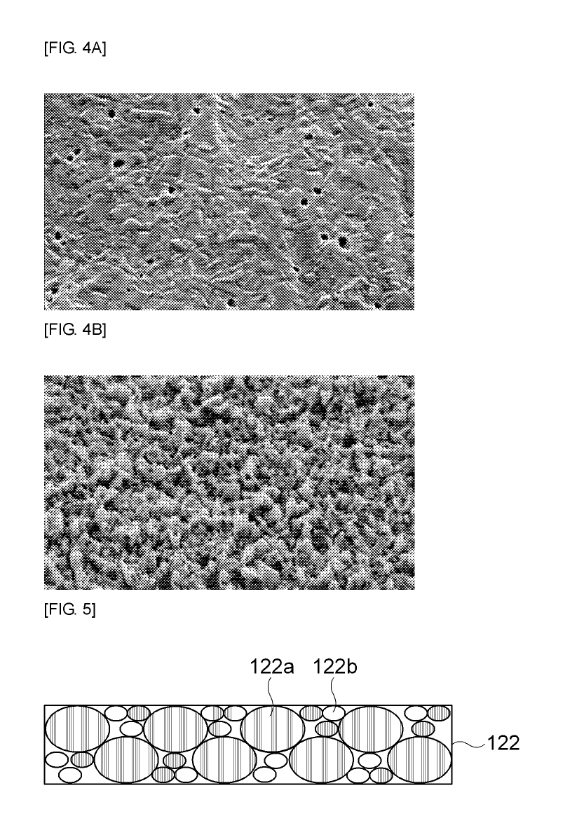

The surface treatment can be performed by blackening the surfaces of the metal layers 111 and 121, FIG. 4a is a view showing the surfaces of the metal layers 111 and 121 before the blacken is performed, FIG. 4b is a view showing the surfaces of the metal layers 111 and 121 after the blacken is performed, as shown in FIG. 4a and FIG. 4b, it can be identified that the roughness can be secured by forming an oxidation layer (123 of FIG. 3a) on the surfaces of the blacken processed metal layers 111 and 121.

Like this, in case when the metal layers 111 and 121 the insulating films 112 and 122 are joined by using the roughness secured oxidation layer, the thermoelectric module can secure the reliability by drastically improving the adhesion force.

On the other hands, although not shown in the drawings, in order to improve the adhesion between the metal electrodes 131 and 132 and the insulating films 112 and 122, the surface of the metal electrode 130, on which the insulating films 131 and 132 are formed, also can be blackened.

The metal layers 111 and 112 may be made of a material including more than one among Cu, Au, Ag, AlN, SiC and Al.

As the following table 1 shows the thermal conductivity of each element constituting the metal layers 111 and 112, as shown in the table 1, for example, the Cu has a thermal conductivity having approximately 400 W/m.K. Like this, since the heat moved by the holes included in the P-type thermoelectric semiconductor 140 and the electrons included in the N-type thermoelectric semiconductor 150 can be rapidly discharged or absorbed thermally through the bottom substrate 120 and the top surface 110, the thermal transmission efficiency of the thermoelectric module can be drastically increased.

TABLE 1

| Material | Thermal conductivity (W/MK) |
|---|---|
| Copper(Cu) | 403 |
| Silver(Ag) | 431 |
| Gold(Au) | 316 |
| Aluminum nitride(AlN) | 270 |
| Silicon carbide(SiC) | 270 |
| Aluminum(Al) | 237 |

It can be constructed to allow the metal layers 111 and 121 to have a thickness ranging from 100 μm to 200 μm. If the thickness of the metal layers 111 and 121 becomes thin, the miniaturization of the thermoelectric module becomes easy, but since there occurs a problem of stability of products due to the weakness of force to support the thermoelectric semiconductor, it is preferable that the thickness is appropriately designed based on the miniaturization and stability of the products.

As the insulating films 112 and 122 are provided to prevent the electric short between the metal layers 111 and 121 and the metal electrode 130, the top substrate 110 and the bottom substrate 120 included in the thermoelectric module 100 in accordance with the present invention can secure the electric insulation by the insulating films 112 and 122.

The insulating films 112 and 122 may be made of a polymer resin and the polymer resin may be made of a material including more than any one of epoxy, poly imide and poly amide.

That is, for example, the epoxy resin can be synthesized by the condensation polymerization between bisphenol A and epichlorohydrin, wherein it can be manufactured with the thermoset material by adding amine curing agent and acid anhydride curing agent.

Since the polymer resin has very excellent electric insulation property, it can allow the metal layers 111 and 121 to be electrically insulated from the metal electrode 130 as well as, since the reaction shrinkage rate is very small and the mechanical properties such as the bending strength or the hardness or the like are very excellent, it can improve the adhesion strength between the top substrate 110 and the metal electrode 130 or the bottom substrate 120 and the metal electrode 130 due to the great adhesion strength.

FIG. 5 is a cross-section view of an insulating film included in the bottom substrate. Referring to FIG. 5, the insulating film 122 can be obtained by filling the ceramic fillers 122a and 122b in the polymer resin.

Since the ceramic fillers 122a and 122b have excellent electric insulation and have high thermal conductivity in comparison with the polymer resin, in case when they are filled in the polymer resin, the efficiency of heat transfer of the thermoelectric module 100 in accordance with the present invention can be improved further.

The ceramic fillers 122a and 122b may be made of a material including more than any one of alumina, aluminum nitride, boron nitride and silica.

As the following table 2 shows the thermal conductivity of each element constituting the ceramic fillers 122a and 122b, referring to the table 2, since the aluminum nitride has the highest thermal conductivity as 270 W/m.K, it is advantageous that the ceramic fillers 122a and 122b are made of aluminum nitride, but it is preferable that they are constructed by appropriately mixing each of the elements based on the manufacturing cost of products.

TABLE 2

| Material | Thermal conductivity (W/MK) |
|---|---|
| Alumina(Al₂O₃) | 30 |
| Boron nitride(BN) | 110 |
| Aluminum nitride(AlN) | 270 |
| Silica(SiO₂) | 10 |

Herein, the ceramic fillers 122a and 122b can be constructed to have content ratio of 70 wt % in comparison with the polymer resin.

Since the ceramic fillers 122a and 122b, as described above, are filled to increase the efficiency of heat transfer of the thermoelectric module 100 in accordance with the present invention, although the efficiency of heat transfer of the thermoelectric module is increased as increasing the content ratio of the ceramic fillers 122a and 122b, on the contrary, since the adhesion strength between the metal layers 111 and 121 and the metal electrode 130 may be decreased due to lowering the content ratio of the polymer resin as increasing the content ratio of the ceramic fillers 122a and 122b, it is preferable that the content ratio of the ceramic fillers 122a and 122b is appropriately designed based on the efficiency of heat transfer and the adhesion strength of the thermoelectric module.

The ceramic fillers 122a and 122b can be constructed that the particle sizes thereof are different from each other. More particularly, the ceramic fillers 122a and 122b can be constructed to include a granulation powder 122a having particle sizes ranging between 2 μm and 3 μm and a fine powder 122b having particle sizes ranging between 0.3 μm and 0.5 μm.

If the ceramic fillers 122a and 122b are constructed that the particles thereof are different from each other in size, the packing factor of the ceramic fillers 122a and 122b is increased to the polymer resin by positioning the fine powder 122b between the granulation powder 122a, accordingly, the efficiency of heat transfer of the thermoelectric module 100 in accordance with the present invention can be further improved.

In the above, although explaining the insulating film included in the bottom substrate 120, the insulating film included in the top substrate 110 can be also formed by filling the ceramic fillers 122a and 122b in the polymer resin.

In order to further improve the efficiency of heat transfer of the thermoelectric module 100 in accordance with the present invention, the metal fillers (not shown) can be filled in the polymer resin to construct the bottom substrate 120 and the top substrate.

The metal filler may be made of a material including more than any one of Cu, Au, Ag, Al and W.

As the following table 3 shows the thermal conductivity of each element constituting the metal layers 111 and 112, referring to table 3, since the silver Ag has the highest thermal conductivity as 431 W/m.K, it is advantageous that the metal filler is made of silver, but it is preferable that it is constructed by appropriately mixing each of the elements based on the manufacturing cost of products.

TABLE 3

| Material | Thermal conductivity (W/MK) |
|---|---|
| Copper(Cu) | 403 |
| Silver(Ag) | 431 |
| Gold(Au) | 316 |
| Aluminum(Al) | 270 |
| Tungsten(W) | 174 |

As shown in the table 2 and the table 3, in general, the thermal conductivity of the metal filler has a value higher than that of the ceramic fillers.

Accordingly, if the content ratio of the metal filler is increased in comparison with the polymer resin, although the efficiency of heat transfer of the thermoelectric module in accordance with the present invention can be increased, if the content ratio of the metal filler exceeds a predetermined value, an electrical path is formed through the contact between the metal fillers, in this result, since the insulating films 112 and 122 cannot secure the electric insulation, it is preferable that the content ration of the metal filler becomes below 50 wt % in comparison with the polymer resin under the condition that the distribution is uniform when the metal filler is filled.

Similar to the particle sizes of the ceramic fillers 122a and 122b, the thermoelectric module 100 in accordance with the present invention can be formed in such a way that the particles of the metal fillers are different from each other in size. More particularly, the ceramic fillers 122a and 122b can be constructed to include a granulation powder 122a having particle sizes ranging between 2 μm and 3 μm and a fine powder 122b having particle sizes ranging between 0.3 μm and 0.5 μm.

In order to further improve the efficiency of heat transfer of the thermoelectric module 100 in accordance with the present invention, the metal fillers and the ceramic fillers 122a and 122b can be filled in the polymer resin at the same time.

The ceramic fillers 122a and 122b may be made of a material including more than any one of alumina, aluminum nitride, boron nitride and silica; and the metal layers 111 and 112 may be made of a material including more than one among Cu, Au, Ag, AlN, SiC and Al.

The ceramic fillers 122a and 122b and the metal fillers have the particle different from each other in size; more particularly, they can include a granulation powder 122a having particle sizes ranging between 2 μm and 3 μm and a fine powder 122b having particle sizes ranging between 0.3 μm and 0.5 μm.

The thickness of the insulating films 112 and 122 may have a value ranging from 10 μm and 30 μm. As the thickness of the insulating films 112 and 122 becomes thick, although the adhesion strength between the metal electrode 130 and the metal layers 111 and 121 can be increased, but since the efficiency of heat transfer of the thermoelectric module in accordance with the present invention is decreased and it is disadvantageous in the miniaturization of products, it is preferable that the thickness of the insulating films 112 and 122 is approximately designed based on the efficiency of heat transfer and the size of the products or the like.

In accordance with the thermoelectric module, it can secure the high efficiency of heat transfer in comparison with the conventional thermoelectric module by using the substrate including the surface treated metal layers so as to secure roughness at one side thereof.

Further, the insulation to the metal electrodes can be secured by including the insulating film on one side of the surface treated metal layers.

And also, the efficiency of heat transfer of the thermoelectric can be further improved by filling the ceramic fillers or the metal fillers in the insulating films.

And also, a heat sink can be easily joined by forming the metal layers with the same material of the heat sink; accordingly, the efficiency of heat transfer of the thermoelectric module can be further improved.

The above-described embodiments and the accompanying drawings are provided as a most preferable example to help understanding of those skilled in the art, not limiting the scope of the present invention. Therefore, the various embodiments of the present invention may be embodied in different forms in a range without departing from the essential concept of the present invention, and the scope of the present invention should be interpreted from the invention defined in the claims. It is to be understood that the present invention includes various modifications, substitutions, and equivalents by those skilled in the art.

What is claimed is:

1. A thermoelectric module provided with a top substrate, a bottom substrate, a metal electrode formed on one surfaces of the top substrate and the bottom substrate and a plurality of P-type thermoelectric semiconductor and a plurality of N-type thermoelectric semiconductor separated between the metal electrodes, the thermoelectric module comprising:
a metal layer surface treated to allow the top substrate, the bottom substrate or the top and bottom substrate to secure roughness at one surface thereof; and
an insulating film formed on the surface treated surfaced.

2. The thermoelectric module according to claim 1, wherein the insulating film is composed of polymer resin.

3. The thermoelectric module according to claim 2, wherein the polymer resin is made of a material including any one among epoxy, poly imide and poly amide.

4. The thermoelectric module according to claim 2, wherein a ceramic filler is filled in the polymer resin.

5. The thermoelectric module according to claim 4, wherein the ceramic filler is made of a material including any one among alumina, aluminum nitride, boron nitride and silica.

6. The thermoelectric module according to claim 4, wherein the ceramic filler is contained more than 70 w % in comparison with the polymer resin.

7. The thermoelectric module according to claim 4, wherein particles of the ceramic filler are different from each other in size.

8. The thermoelectric module according to claim 4, wherein the ceramic filler includes granulation powder having particle sizes ranging between 2 μm and 3 μm and fine powder having particle sizes ranging between 0.3 μm and 0.5 μm.

9. The thermoelectric module according to claim 2, wherein a metal filler is filled in the polymer resin.

10. The thermoelectric module according to claim 9, wherein the metal filler is made of a material including more than one of Cu, Ag, Au, Al and W.

11. The thermoelectric module according to claim 9, wherein the metal filler has content below 50 wt % in comparison with the polymer resin.

12. The thermoelectric module according to claim 9, wherein each of the metal fillers has a different size.

13. The thermoelectric module according to claim 9, wherein the metal filler includes granulation powder having particle sizes ranging between 2 μm and 3 μm and fine powder having particle sizes ranging between 0.3 μm and 0.5 μm.

14. The thermoelectric module according to claim 2, wherein the ceramic filler and the metal filler is filled in the polymer resin.

15. The thermoelectric module according to claim 14, wherein the ceramic filler is made of a material including more than any one of alumina, aluminum nitride, boron nitride and silica; and
the metal filler is made of a material including more than any one of Cu, Ag, Au, Al and W.

16. The thermoelectric module according to claim 14, wherein the ceramic fillers and the metal fillers are different in size.

17. The thermoelectric module according to claim 14, wherein the ceramic filler and the metal filler includes granulation powder having particle sizes ranging between 2 μm and 3 μm and fine powder having particle sizes ranging between 0.3 μm and 0.5 μm.

18. The thermoelectric module according to claim 1, wherein the insulating film has a thickness ranging from 10 μm to 30 μm.

19. The thermoelectric module according to claim 1, wherein the metal layer has a thickness ranging from 100 μm to 200 μm.

20. The thermoelectric module according to claim 1, wherein the metal layer is made of a material including more than any one of Cu, Au, Ag, AlN, SiC and Al.
